(19) United States
(12) Patent Application Publication
(10) Pub. No.: US 2023/0012170 A1
(43) Pub. Date: Jan. 12, 2023

(54) HEAT CONDUCTION STRUCTURE WITH LIQUID-GAS SPLIT MECHANISM

(71) Applicant: TAIWAN MICROLOOPS CORP., New Taipei City (TW)

(72) Inventors: Chun-Hung LIN, New Taipei City (TW); Han-Lin CHEN, New Taipei City (TW)

(21) Appl. No.: 17/503,262

(22) Filed: Oct. 15, 2021

(30) Foreign Application Priority Data
Jul. 7, 2021 (TW) 110124982

(51) Int. Cl. H05K 7/20

(52) U.S. Cl. CPC H05K 7/20336

(57) ABSTRACT

A heat conduction structure includes a shell, a wick structure, a separating sheet, and a working fluid. The shell includes a chamber. The chamber is divided into an evaporation room, a condensation room and a connection room formed between the evaporation room and the condensation room. The wick structure covers an inner bottom wall of the chamber. The separating sheet is received in the connection room and stacked on the wick structure. An airflow channel is formed between the separating sheet and the inner top wall of the connection room. The working fluid is disposed in the chamber. Therefore, the liquid working fluid and the gaseous working fluid are split by the separating sheet to increase the heat dissipating efficiency of the heat conduction structure.

### BACKGROUND

### Technical Field

The disclosure relates to a vapor chamber, particularly to a heat conduction structure with a liquid-gas split mechanism.

### Related Art

With the continuous improvement of operating speed of electronic components, the heat being generated becomes higher and higher. To effectively solve the problem of high heat, the industry has widely utilized vapor chambers with great properties of heat conduction. However, the performance of heat conduction of vapor chambers still has a space of improvement.

A vapor chamber includes an upper shell and a lower shell. The inner spaces of the upper shell and the lower shell are separately disposed with a wick structure, then the upper shell and the lower shell are welded, a working fluid is filled into the upper shell and the lower shell, and finally a degassing and sealing process is implemented to finish the manufacturing process.

However, a related-art vapor chamber has the following drawbacks. When a vapor chamber is designed with a portion with a small cross-sectional area and the gaseous working fluid flows through the portion, the flow speed of the gaseous working fluid is increased. The gaseous working fluid with increased flow speed drags the returning liquid working fluid and blocks the returning liquid working fluid at the portion with a small cross-sectional area. This may cause undesired conditions such as dry-out.

In view of this, the inventors have devoted themselves to the above-mentioned related art, researched intensively and cooperated with the application of science to try to solve the above-mentioned problems. Finally, the disclosure which is reasonable and effective to overcome the above drawbacks is provided.

### SUMMARY

The disclosure provides a heat conduction structure with a liquid-gas split mechanism, which utilizes splitting the liquid working fluid and the gaseous working fluid by the separating sheet to improve the heat dissipating efficiency of the heat conduction structure.

In an embodiment of the disclosure, the disclosure provides a heat conduction structure with a liquid-gas split mechanism, which includes a shell, a wick structure, a separating sheet, and a working fluid. The shell includes a chamber. The chamber is divided into an evaporation room, a condensation room and a connection room formed between the evaporation room and the condensation room. The wick structure covers an inner bottom wall of the chamber. The separating sheet is received in the connection room and stacked on the wick structure. An airflow channel is formed between the separating sheet and the inner top wall of the connection room. The working fluid is disposed in the chamber.

Accordingly, the liquid working fluid and the gaseous working fluid are split by the separating sheet. The liquid working fluid flows from the condensation room to the evaporation room along the wick structure and the gaseous working fluid flows from the evaporation room to the condensation room along the airflow channel. The liquid working fluid is not interfered by the gaseous working fluid so as to smoothly return to the evaporation room. The heat accumulation or dry-out of the heat conduction structure may also be avoided. Thus, the heat conduction structure possesses desirable heat dissipating efficiency.

Accordingly, when the inner peripheral size of the connection room is less than the inner peripheral size of the evaporation room, the flow speed of the gaseous working fluid may be increased because the gaseous working fluid flows through the connection room with a smaller cross-sectional area. Since the separating sheet splits the gaseous working fluid and the liquid working fluid, the liquid working fluid is blocked by the accelerated gaseous working fluid and smoothly returns to the evaporation room. This further enhances the heat dissipating efficiency of the heat conduction structure.

### BRIEF DESCRIPTION OF THE DRAWINGS

FIG. 1 is an exploded view of the heat conduction structure of the disclosure;

FIG. 2 is an assembled view of the heat conduction structure of the disclosure;

FIG. 3 is a cross-sectional view of the heat conduction structure of the disclosure;

FIG. 4 is a cross-sectional view of the heat conduction structure of the disclosure in use;

FIG. 5 is another cross-sectional view of the heat conduction structure of the disclosure in use; and

FIG. 6 is a cross-sectional view of another embodiment of the heat conduction structure of the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

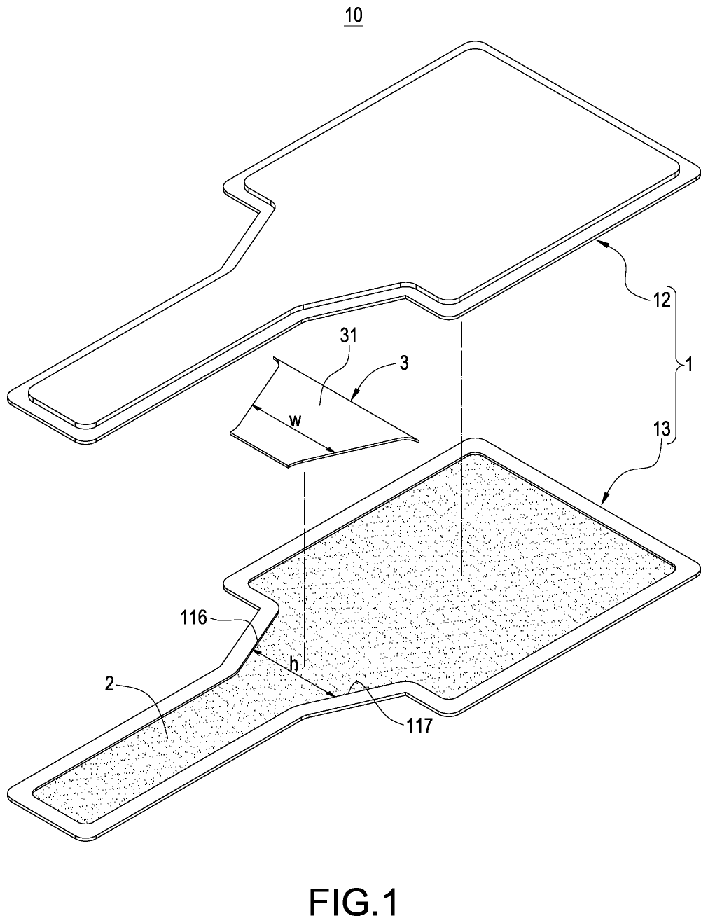

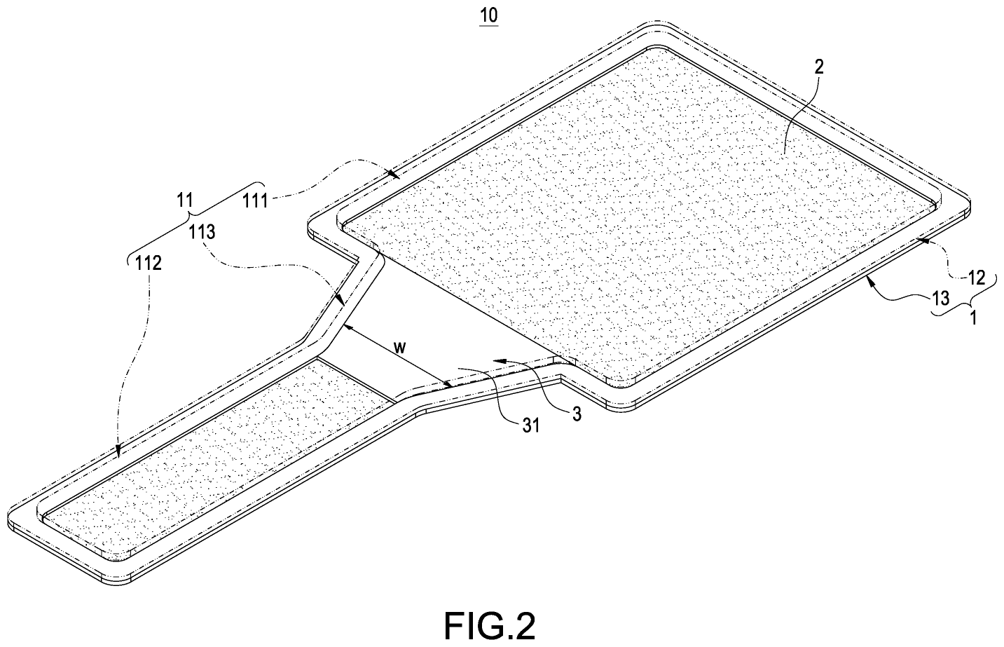

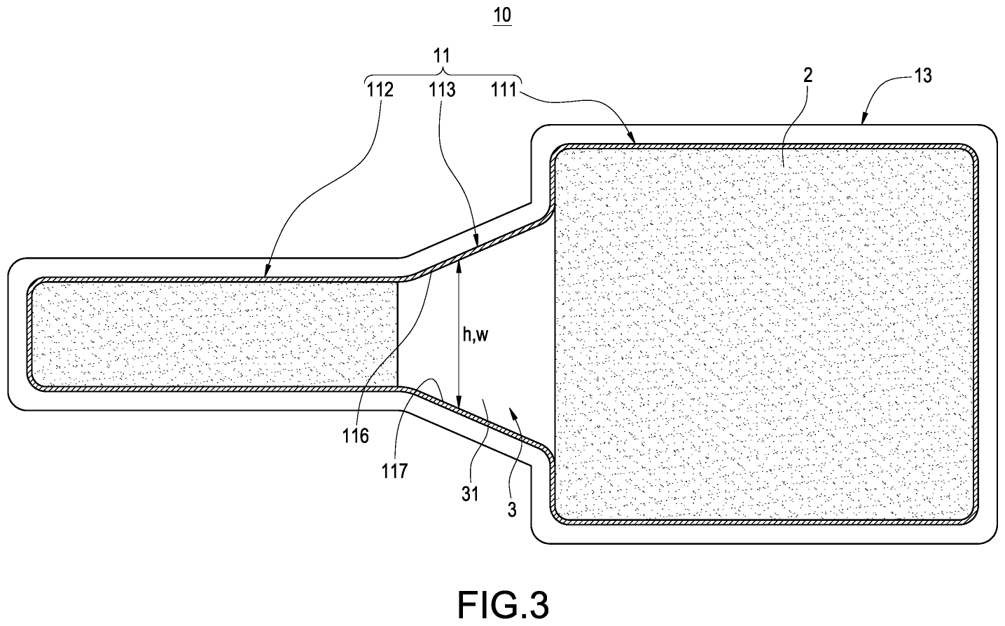

Please refer to FIGS. 1-5. The disclosure provides a heat conduction structure with a liquid-gas split mechanism. The heat conduction structure includes a shell 1, a wick structure 2, a separating sheet 3 and a working fluid.

As shown in FIGS. 1-5, the shell 1 includes a chamber 11. The chamber 11 is divided into an evaporation room 111, a condensation room 112 and a connection room 113 formed between the evaporation room 111 and the condensation room 112. The working fluid is disposed in the chamber 111. The working fluid is a liquid which may generate gas-liquid phase transition, such as pure water.

In addition, an inner peripheral size of the connection room 113 is less than an inner peripheral size of the evaporation room 111. The shell 1 includes an upper shell plate 12 and a lower shell plate 13 assembled with each other.

In detail, two lateral sides of the connection room 113 have an inner left wall 116 and an inner right wall 117. A distance h is between the inner left wall 116 and the inner right wall 117. The distance h tapers off from the evaporation room 111 toward the condensation room 112.

As shown in FIGS. 1-5, the wick structure 2 covers an inner bottom wall 114 of the inside bottom of the chamber 11. The wick structure 2 is configured by one of a sintered powder, a metal mesh, a porous material, a foam material, and a grooved structure to transport the liquid working fluid through the capillary adsorption.

As shown in FIGS. 1-5, the separating sheet 3 is a metal foil such as a copper foil or an aluminum foil. The separating sheet 3 is received in the connection room 3 and stacked on the wick structure 2. An airflow channel s is formed between the separating sheet 3 and the inner top wall 115 of the connection room 113.

In detail, the shape of the separating sheet 3 in top view matches the cross-sectional shape inside the connection room 113 (or the inner shape of the connection room 113 in top view) so as to make the separating sheet 3 completely cover the wick structure 2 of the connection room 113. A width w of the separating sheet 3 tapers off from the evaporation room 111 toward the condensation room 112. In the embodiment, the separating sheet 3 is, but not limited to, a trapezoidal sheet 31.

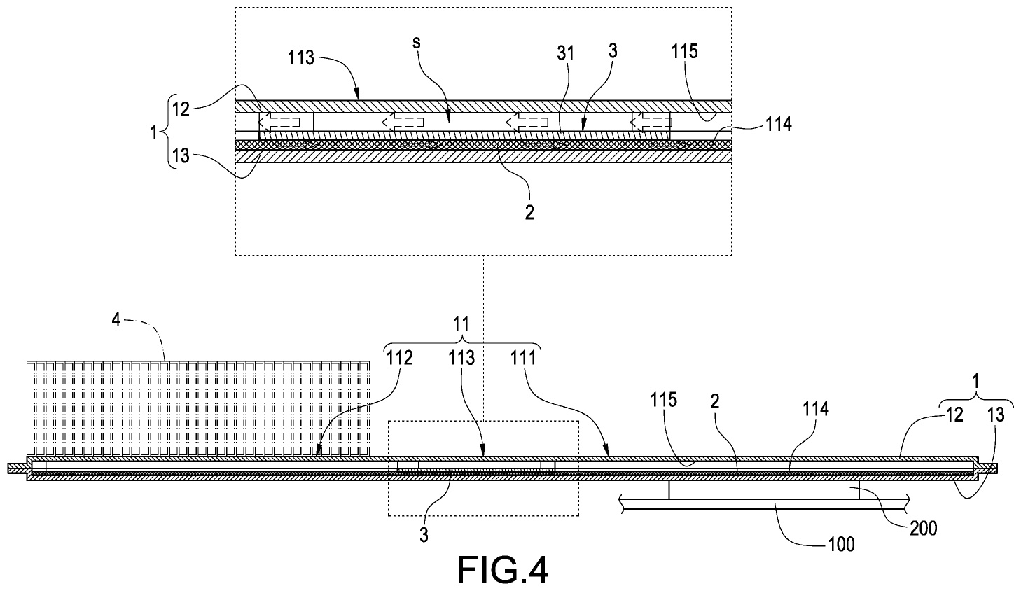

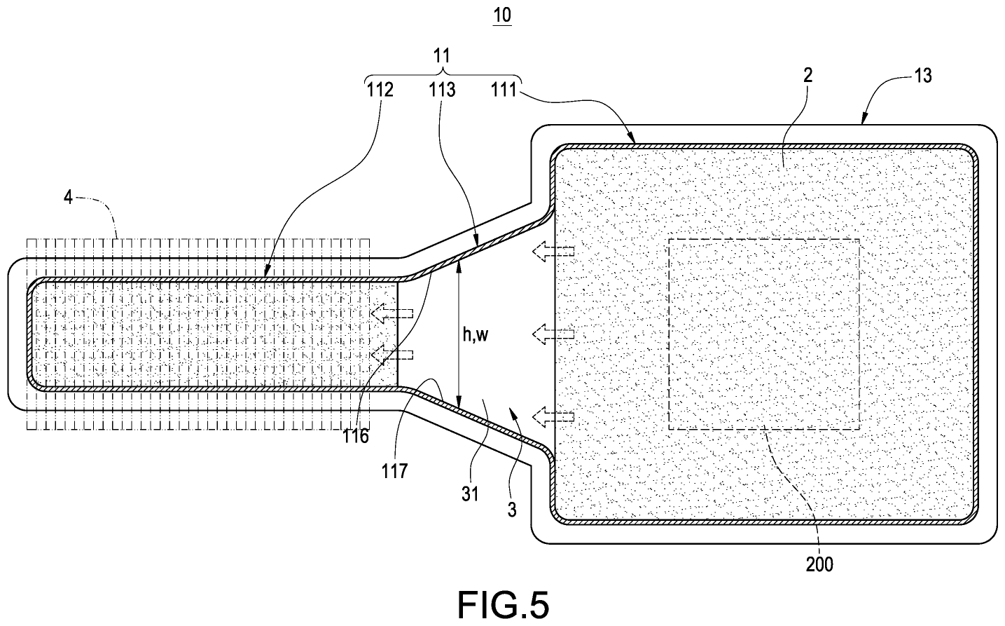

As shown in FIGS. 4-5, the heat conduction structure 10 of the disclosure further includes multiple heat dissipating fins 4, which are disposed outside the condensation room 112.

The outside of the evaporation room 111 is thermally attached on a heat generating element 200 on a circuit board 100. The liquid working fluid of the evaporation room 111 absorbs the heat from the heat generating element 200 to become the gaseous working fluid. When the gaseous working fluid reaches the condensation room 112, the gaseous working fluid transfers heat to the heat dissipating fins 4 to become liquid working fluid. The liquid working fluid flows back to the evaporation room 111 along the wick structure 2 to form a thermal cycle.

As shown in FIGS. 4-5, the using status of the heat conduction structure of the disclosure utilizes the separating sheet 3 received in the connection room 113 and stacked on the wick structure 2 and the airflow channel s formed between the separating sheet 3 and the inner top wall 115 of the connection room 113 to make the liquid working fluid flow from the condensation room 112 to the evaporation room 111 along the wick structure 2 and the gaseous working fluid flow from the evaporation room 111 to the condensation room 112 along the airflow channel s. Therefore, the liquid working fluid and the gaseous working fluid are split by the separating sheet 3. The liquid working fluid does not interfere with the gaseous working fluid so as to smoothly return to the evaporation room 111. The heat accumulation or dry-out of the heat conduction structure 10 may be avoided. Thus, the heat conduction structure 10 possesses great heat dissipating efficiency.

In addition, when the inner peripheral size of the connection room 113 is less than the inner peripheral size of the evaporation room 111, the flow speed of the gaseous working fluid is increased because the gaseous working fluid flows through the connection room 113 with a smaller cross-sectional area. Since the separating sheet 3 splits the gaseous working fluid and the liquid working fluid, the liquid working fluid is not blocked by the accelerated gaseous working fluid and smoothly returns to the evaporation room 111. That further enhances the heat dissipating efficiency of the heat conduction structure.

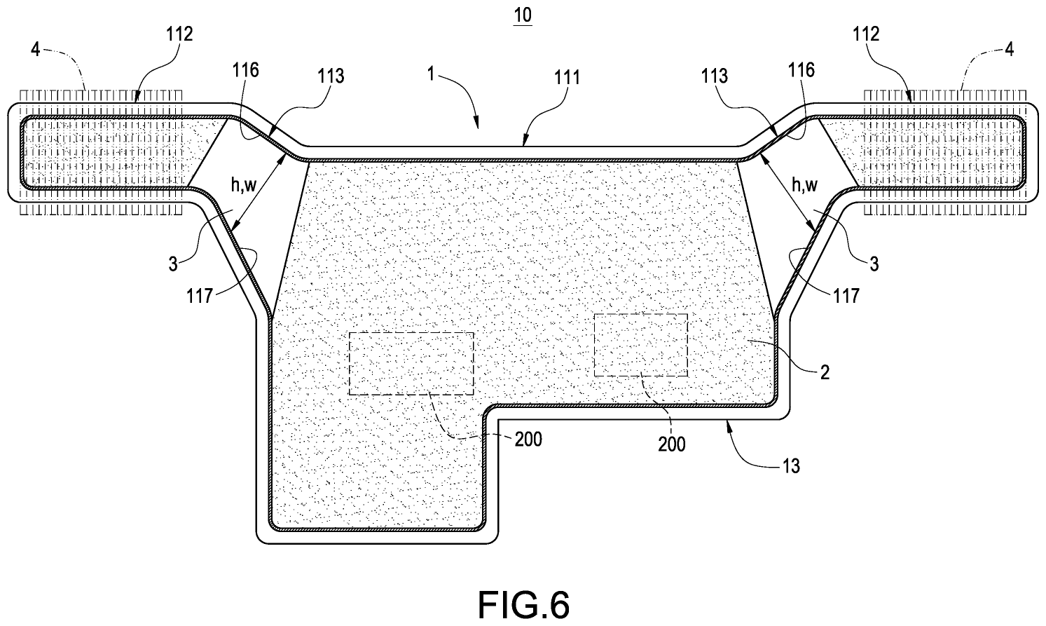

Please refer to FIG. 6, which shows another embodiment of the heat conduction structure of the disclosure. The embodiment of FIG. 6 is similar to the embodiment of FIGS. 1-5. The embodiment of FIG. 6 differs from the embodiment of FIGS. 1-5 by the number of the condensation room 112, the number of the connection room 113 and the number of the separating sheet 3 being multiple respectively.

In detail, the outside of the evaporation room 111 may be thermally attached with multiple heat generating elements 200. The multiple condensation rooms 112 are disposed outside the evaporation room 111. Each connection room 113 communicates with the evaporation room 111 and each condensation room 112. Each separating sheet 3 is received in each connection room 113 and stacked on the wick structure 2 so as to make the heat generated from the heat generating elements 200 be transferred to the multiple condensation rooms 112 through the evaporation room 111 to be dissipated. That may effectively increase the heat dissipating efficiency of the heat conduction structure 10.

While this disclosure has been described by means of specific embodiments, numerous modifications and variations could be made thereto by those skilled in the art without departing from the scope and spirit of this disclosure set forth in the claims.

What is claimed is:

1. A heat conduction structure with a liquid-gas split mechanism, the heat conduction structure comprising:
a shell, comprising a chamber, the chamber divided into an evaporation room, a condensation room and a connection room disposed between the evaporation room and the condensation room;
a wick structure, covering an inner bottom wall of the chamber;
a separating sheet, received in the connection room, stacked on the wick structure, and an airflow channel disposed between the separating sheet and the inner top wall of the connection room; and
a working fluid, disposed in the chamber.

2. The heat conduction structure of claim 1, wherein an inner peripheral size of the connection room is less than an inner peripheral size of the evaporation room.

3. The heat conduction structure of claim 2, wherein the connection room comprises an inner left wall and an inner right wall, the inner left wall is separated from the inner right wall with a distance, and the distance tapers off from the evaporation room toward the condensation room.

4. The heat conduction structure of claim 3, wherein a width of the separating sheet tapers off from the evaporation room toward the condensation room, and the separating sheet is a trapezoidal sheet.

5. The heat conduction structure of claim 1, wherein a shape of the separating sheet in top view matches an inner shape of the connection room in top view, and the separating sheet covers the wick structure of the connection room.

6. The heat conduction structure of claim 1, wherein the separating sheet is a copper foil or an aluminum foil.

7. The heat conduction structure of claim 1, further comprising: multiple heat dissipating fins, disposed outside the condensation room.

8. The heat conduction structure of claim 1, wherein the wick structure is configured by one of a sintered powder, a metal mesh, a porous material, a foam material, and a grooved structure.

9. The heat conduction structure of claim 1, wherein the shell comprises an upper shell plate and a lower shell plate assembled with each other.

10. The heat conduction structure of claim 1, wherein an amount of each of the condensation room, an amount of the connection room and an amount of the separating sheet are multiple respectively, the multiple condensation rooms are disposed outside the evaporation room, each connection room separately communicates with the evaporation room and each condensation room, and each separating sheet is received in each connection room and stacked on the wick structure.
